(19) United States
(12) Patent Application Publication
(10) Pub. No.: US 2007/0045682 A1
(43) Pub. Date: Mar. 1, 2007

(54) Imager with gradient doped EPI layer

(76) Inventors: Sungkwon C. Hong, Boise, ID (US); Richard A. Mauritzson, Meridian, ID (US); Ralph Kauffman, Boise, ID (US)

Correspondence Address: DICKSTEIN SHAPIRO LLP, 1825 EYE STREET NW, Washington, DC, 20006-5403, US

(21) Appl. No.: 11/214,932

(22) Filed: Aug. 31, 2005

(51) Int. Cl. H01L 31/113

(52) U.S. Cl. 257/292

(57) ABSTRACT

A pixel cell including a substrate of a first conductivity type over an epitaxial layer of a second conductivity type. The epitaxial layer has a dopant gradient, wherein the dopant concentration decreases from a surface of the epitaxial layer adjacent the substrate to the surface of the epitaxial layer opposite the substrate. A photo-conversion device is at a surface of the epitaxial layer.

### FIELD OF THE INVENTION

The present invention relates to the field of semiconductor devices, particularly to improved isolation techniques for image sensors.

### BACKGROUND OF THE INVENTION

CMOS image sensors are increasingly being used as low cost imaging devices. A CMOS image sensor circuit includes a focal plane array of pixel cells, each one of the cells includes a photogate, photoconductor, or photodiode having an associated charge accumulation region within a substrate for accumulating photo-generated charge. Each pixel cell may include a transistor for transferring charge from the charge accumulation region to a sensing node and a transistor for resetting the sensing node to a predetermined charge level prior to charge transference. The pixel cell may also include a source follower transistor for receiving and amplifying charge from the sensing node and an access transistor for controlling the readout of the cell contents from the source follower transistor.

In a CMOS image sensor, the active elements of a pixel cell perform the necessary functions of: (1) photon to charge conversion; (2) accumulation of image charge; (3) transfer of charge to the sensing node accompanied by charge amplification; (4) resetting the sensing node to a known state; (5) selection of a pixel for readout; and (6) output and amplification of a signal representing pixel charge from the sensing node.

CMOS image sensors of the type discussed above are generally known as discussed, for example, in Nixon et al., “256×256 CMOS Active Pixel Sensor Camera-on-a-Chip,” IEEE Journal of Solid-State Circuits, Vol. 31(12), pp. 2046-2050 (1996); and Mendis et al., “CMOS Active Pixel Image Sensors,” IEEE Transactions on Electron Devices, Vol. 41(3), pp. 452-453 (1994). See also U.S. Pat. Nos. 6,177,333 and 6,204,524, which describe the operation of conventional CMOS image sensors and are assigned to Micron Technology, Inc., the contents of which are incorporated herein by reference.

A schematic diagram of a conventional four transistor (4T) CMOS pixel cell 10 is shown in FIG. 1. The CMOS pixel cell 10 generally comprises a photo-conversion device 23 for generating and collecting charge generated by light incident on the pixel cell 10, and a transfer transistor 17 for transferring photoelectric charges from the photo-conversion device 23 to a sensing node, typically a floating diffusion region 5. The floating diffusion region 5 is electrically connected to the gate of an output source follower transistor 19. The pixel cell 10 also includes a reset transistor 18 for resetting the floating diffusion region 5 to a predetermined voltage Vₐₐ₋ₚᵢₓ; and a row select transistor 16 for outputting a signal from the source follower transistor 19 to an output terminal in response to an address signal.

FIG. 2 is a cross-sectional view of a portion of the pixel cell 10 of FIG. 1 showing the photo-conversion device 23, transfer transistor 17 and reset transistor 18. The pixel cell 10 is isolated from adjacent pixel cells and devices by a shallow trench isolation region 37. The exemplary photo-conversion device 23 may be formed as a pinned photodiode having, e.g., a p-n-p construction comprising a p-type surface layer 22 and an n-type photodiode region 21 within a uniformly lightly doped p-type epitaxial layer 11. The p-type epitaxial layer 11 is over a heavily doped p-type substrate 12. The photodiode photo-conversion device 23 is adjacent to the transfer transistor 17. The reset transistor 18 is on a side of the transfer transistor 17 opposite the photo-conversion device 23. As shown in FIG. 2, the reset transistor 18 includes a source/drain region 2. The floating diffusion region 5 is located between the transfer and reset transistors 17, 18.

In the CMOS pixel cell 10 depicted in FIGS. 1 and 2, electrons are generated by light incident on the photo-conversion device 23 and are stored in the n-type photodiode region 21. These charges are transferred to the floating diffusion region 5 by the transfer transistor 17 when the transfer transistor 17 is activated. The source follower transistor 19 produces an output signal based on the transferred charges applied to its gate. A maximum output signal is proportional to the number of electrons extracted from the n-type photodiode region 21.

Recently, use of an n-type substrate has been investigated as a means to achieve reduced cross-talk. The n-type substrate, however, results in reduced quantum efficiency at longer wavelengths. It would be desirable to have an image sensor that provides reduced cross-talk achieved by the use of an n-type substrate with minimized reduction in quantum efficiency.

### BRIEF SUMMARY OF THE INVENTION

A pixel cell including a substrate of a first conductivity type over an epitaxial layer of a second conductivity type. The epitaxial layer has a dopant gradient, wherein the dopant concentration decreases from the bottom of the epitaxial layer adjacent the substrate to the surface of the epitaxial layer opposite the substrate. A photo-conversion device is at a surface of the epitaxial layer.

### BRIEF DESCRIPTION OF THE DRAWINGS

The foregoing and other aspects of the invention will be better understood from the following detailed description of the invention, which is provided in connection with the accompanying drawings, in which:

FIG. 1 is a schematic diagram of a conventional pixel cell;

FIG. 2 is a cross-sectional view of a conventional pixel cell;

FIG. 3 is a cross-sectional view of a pixel cell according to an exemplary embodiment of the invention;

FIGS. 4A-4D depicts the pixel cell of FIG. 3 at different stages of processing;

FIGS. 5A-5C are graphs representing the dopant profiles of the epitaxial layer of the pixel cell of FIG. 3 according to exemplary embodiments of the invention;

FIG. 6 is a block diagram of a CMOS image sensor according to an exemplary embodiment of the invention; and

FIG. 7 is a block diagram of a computer processor system incorporating the CMOS image sensor of FIG. 6.

### DETAILED DESCRIPTION OF THE INVENTION

In the following detailed description, reference is made to the accompanying drawings, which form a part hereof and illustrate specific embodiments in which the invention may be practiced. In the drawings, like reference numerals describe substantially similar components throughout the several views. These embodiments are described in sufficient detail to enable those skilled in the art to practice the invention, and it is to be understood that other embodiments may be utilized, and that structural, logical and electrical changes may be made without departing from the spirit and scope of the present invention.

The terms “wafer” and “substrate” are to be understood as including silicon, silicon-on-insulator (SOI), silicon-on-sapphire (SOS), and silicon-on-nothing (SON) technology, doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions or junctions in the base semiconductor structure or foundation. In addition, the semiconductor need not be silicon-based, but could be based on silicon-germanium, germanium, or gallium-arsenide.

The term “pixel” or “pixel cell” refers to a picture element unit cell containing a photo-conversion device and transistors for converting electromagnetic radiation to an electrical signal. For purposes of illustration, a portion of a representative pixel cell is illustrated in the figures and description herein, and typically fabrication of all pixel cells in an image sensor will proceed concurrently and in a similar fashion.

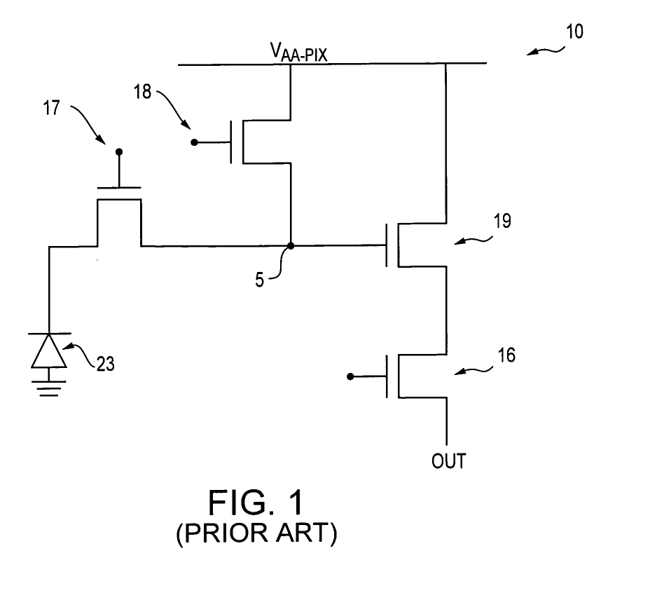

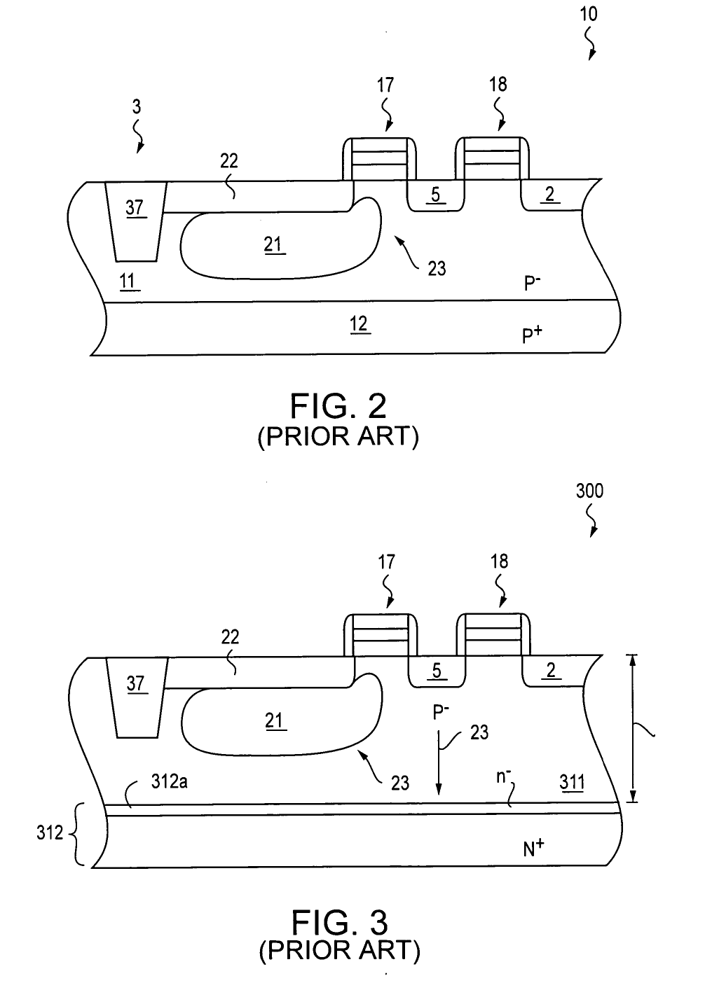

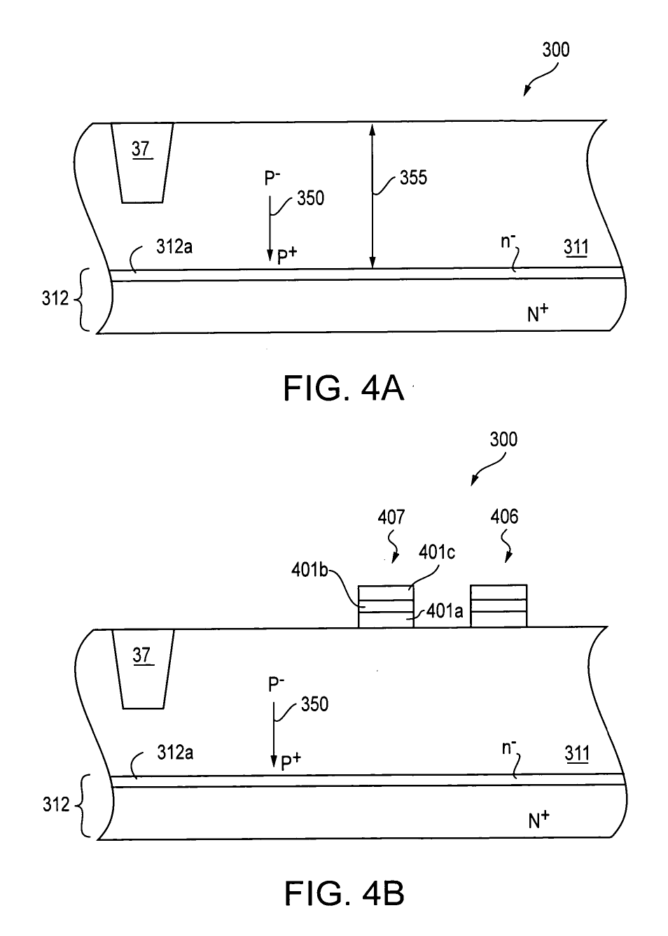

FIG. 3 is a cross-sectional view of a pixel cell 300 according to an exemplary embodiment of the invention. The pixel cell 300 is similar to the pixel cell 10 depicted in FIGS. 1 and 2, except that the pixel cell 300 includes a gradient doped 350 p-type epitaxial layer 311 over an n-type substrate 312. The epitaxial layer 311 has a thickness 355, which can be between about 2 μm and about 20 μm.

In the illustrated embodiment, the n-type substrate 312 is heavily doped and, preferably has a dopant concentration between about 1×10¹⁷ atoms/cm³ to about 5×10¹⁸ atoms/cm³. Alternatively the substrate 312 may be lightly doped. Optionally, the substrate 312 includes a lightly doped n-type layer 312a at an upper surface adjacent the epitaxial layer 311. The dopant concentration of the layer 312a is about 1×10¹⁴ atoms/cm³ to about 5×10¹⁷ atoms/cm³. Alternatively, the lightly doped n-type layer 312a could instead be at the bottom surface of the epitaxial layer 311.

The p-type epitaxial layer 311 dopant gradient 350 has a dopant concentration that increases from the upper surface of the epitaxial layer 311 toward the bottom surface of the epitaxial layer 311, which interfaces with the substrate 312. For example, in one exemplary embodiment, the dopant concentration at the surface of the epitaxial layer 311 is about 1×10¹⁴ atoms/cm³ to about 5×10¹⁵ atoms/cm³, and changes in a gradient manner to the bottom surface of the epitaxial layer 311, which has a dopant concentration of about 5×10¹⁶ atoms/cm³ to about 5×10¹⁸ atoms/cm³ or more.

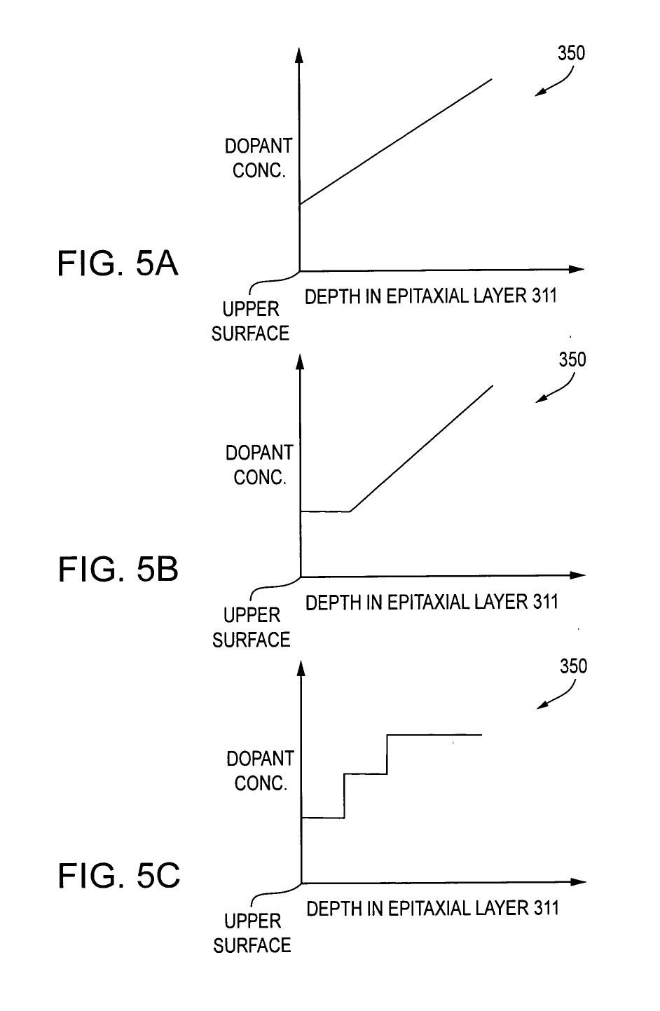

According to one exemplary embodiment, the dopant gradient 350 is a uniform linear gradient 350. As shown in FIG. 5A, the dopant concentration increases uniformly in a linear manner from the upper surface of the epitaxial layer 311 toward the bottom surface of the epitaxial layer 311. In another exemplary embodiment shown in FIG. 5B, the gradient 350 can be configured such that the epitaxial layer 311 can have a uniform doped region at the upper surface. The dopant concentration of the uniform doped region can be about 1×10¹⁴ atoms/cm³ to about 5×10¹⁵ atoms/cm³. Alternatively, the, the dopant gradient 350 can be a stepped gradient 350. As shown in FIG. 5C, the dopant concentration increases in a step-wise manner from the upper surface of the epitaxial layer 311 toward the bottom surface of the epitaxial layer 311. While FIG. 5C shows three dopant concentration levels additional dopant concentration levels can be used. Further, while the increases in dopant concentration are shown as having equal magnitudes, the increases in dopant concentration need not be equal. Other gradient configurations can also be employed.

In a pixel cell having a uniformly, lightly doped p-type epitaxial layer and an N-type substrate, the pn junction at the interface of the epitaxial layer and substrate results in a depletion region. Such a depletion region results in reduced quantum efficiency, particularly for longer wavelengths.

In the present invention, the increased p-type dopant concentration at the interface of the epitaxial layer 311 and the substrate 312 serves to narrow the depletion region at the pn junction. Additionally, the dopant gradient 350 creates a vertical electric field that serves to induce electrons toward the surface of the epitaxial layer 311 where such electrons can be collected by the photo-conversion device 23. (Although the photo-conversion device is depicted as a pinned photodiode, it could instead be another type of photo-conversion device, such as a non-pinned photodiode, or photogate, among others.) Accordingly, in addition to minimizing the loss of quantum efficiency at longer wavelengths, the invention also serves to maintain photon sensitivity and reduce image lag.

The quantum efficiency of silicon is a function of the wavelength of incident light. The absorption coefficient and quantum efficiency are reduced significantly at wavelengths longer than about 750 nm. Many image sensor applications, e.g., automotive applications, require the sensing of infrared and near-infrared wavelengths (e.g., between about 800 nm to about 1μ). To increase quantum efficiency at longer wavelengths, a thicker epitaxial layer, e.g., greater than about 12 μm can be used. In a conventional pixel cell, however, a thicker epitaxial layer causes greater image lag and increased cross talk. By using the epitaxial layer 311 having the dopant gradient 350 and the n-type substrate 312, the present invention enables use of a thicker epitaxial layer 311 (e.g., for use at longer wavelengths) with increased quantum efficiency and improved cross talk and image lag. In addition, the use of the n-type substrate 312 when positively biased provides a reduction of bulk substrate generated dark current.

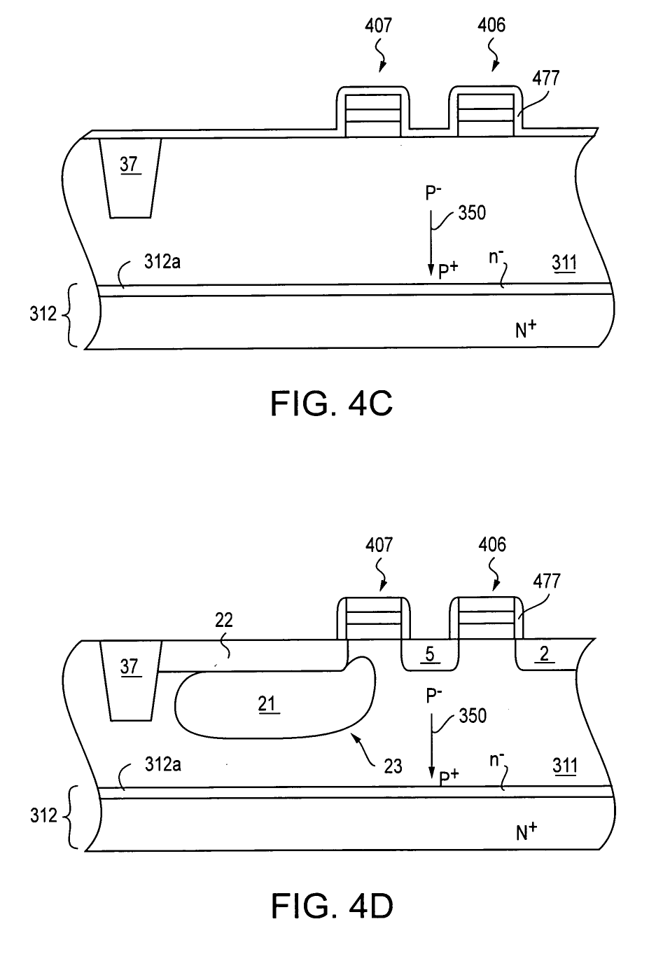

FIGS. 4A-4D depict the formation of pixel cell 300 according to an exemplary embodiment of the invention. No particular order is required for any of the actions described herein, except for those logically requiring the results of prior actions. Accordingly, while the actions below are described as being performed in a general order, the order is exemplary only and can be altered if desired.

As illustrated in FIG. 4A, an n-type substrate 312 is provided. In the illustrated embodiment the substrate 312 is heavily doped with an optional lightly doped n-type layer 312a at the upper surface. An epitaxial layer 311 is grown to a thickness 355 over the substrate 312. The thickness 355 can be between about 2 μm and about 20 μm. The epitaxial layer 311 is doped with a p-type dopant (e.g., boron, indium, or any other suitable p-type dopant). According to one exemplary technique for achieving a uniform linear gradient (FIG. 5A), the gas flow providing the dopant is changed in a linear manner during the epitaxy process. Where a uniformly doped region is desired at the upper surface of the epitaxial layer 311 (FIG. 5B), the gas flow is held constant for the last portion of the epitaxy process. Alternatively, to achieve a stepped gradient as depicted by FIG. 5C, the gas flow is changed abruptly at desired points during the epitaxy process. Preferably, the epitaxial layer 311 is doped such that the upper surface of the epitaxial layer 311 is lightly doped and the bottom surface (i.e., closest to the substrate 312) of the epitaxial layer 311 is heavily doped. For example, in one exemplary embodiment, the dopant concentration at the surface of the epitaxial layer 311 is about 1×10¹⁴ atoms/cm³, to about 5×10¹⁵ atoms/cm³, and changes in a gradient manner to the bottom surface of the epitaxial layer 311, which has a dopant concentration of about 5×10¹⁶ atoms/cm³ to about 5×10¹⁸ atoms/cm³ or more.

FIG. 4B depicts the formation of a shallow trench isolation (STI) region 37 in the substrate 311. The STI region 37 can be formed by any known technique. For example, a patterned photoresist layer (not shown) is used as a mask for an etching process. The STI region 37 is filled with a dielectric material, e.g., an oxide material, such as a silicon oxide, such as high density plasma (HDP) oxide, SiO or silicon dioxide (SiO₂); oxynitride; a nitride material, such as silicon nitride; silicon carbide; a high temperature polymer; or other suitable dielectric material.

FIG. 4B also depicts the formation of the transfer transistor 17 (FIG. 3) gate stack 407 and the reset transistor 18 (FIG. 3) gate stack 406. Although not shown, the source follower and row select transistors 19, 16 (FIG. 1), respectively, can be formed concurrently with the transfer and reset transistors 17, 18 as described below.

To form the transistor gate stacks 407, 406 as shown in FIG. 4B, a first insulating layer 401a of, for example, silicon oxide is grown or deposited on the epitaxial layer 311. The first insulating layer 401a serves as the gate oxide layer for the subsequently formed transistor gate 401b. Next, a layer of conductive material 401b is deposited over the oxide layer 401a. The conductive layer 401b serves as the gate electrode for the transistors 17, 18 (FIG. 3). The conductive layer 401b may be a layer of polysilicon, which may be doped to a second conductivity type, e.g., n-type. A second insulating layer 401c is deposited over the conductive layer 401b. The second insulating layer 401c may be formed of, for example, an oxide (SiO₂), a nitride (silicon nitride), an oxynitride (silicon oxynitride), ON (oxide-nitride), NO (nitride-oxide), or ONO (oxide-nitride-oxide).

The gate stack layers 401a, 401b, 401c may be formed by conventional methods, such as grown in a furnace, chemical vapor deposition (CVD) or plasma enhanced chemical vapor deposition (PECVD), among others. The layers 401a, 401b, 401c are then patterned and etched to form the multilayer gate stacks 407, 406 shown in FIG. 4C.

The invention is not limited to the structure of the gate stacks 407, 406 described above. Additional layers may be added or the gate stacks 407, 406 may be altered as is desired and known in the art. For example, a silicide layer (not shown) may be formed between the gate electrodes 401b and the second insulating layers 401c. The silicide layer may be included in the gate stacks 407, 406, or in all of the transistor gate stack structures in an image sensor circuit, and may be titanium silicide, tungsten silicide, cobalt silicide, molybdenum silicide, or tantalum silicide. This additional conductive layer may also be a barrier layer/refractor metal, such as titanium nitride/tungsten (TiN/W) or tungsten nitride/tungsten (WNₓ/W), or it could be formed entirely of tungsten nitride (WNₓ).

FIG. 4C depicts the formation of a dielectric layer 477. Layer 477 may be any appropriate dielectric material, such as silicon dioxide, silicon nitride, an oxynitride, or tetraethyl orthosilicate (TEOS), among others, formed by methods known in the art.

The dielectric layer 477 is patterned and etched such that remaining portions form sidewall spacers on the transfer gate stack 407 and the reset gate stack 406. Alternatively, layer 477 can be patterned and etched such to form a spacer on a single sidewall of the reset gate stack 406, while remaining over the transfer gate stack 407, the photodiode 23, the floating diffusion region 5, and a portion of the reset gate stack 406.

As depicted in FIG. 4D, a doped n-type region 21 is implanted in the epitaxial layer 311 (for the photo-conversion device (photodiode) 23 of FIG. 3). For example, a layer of photoresist (not shown) may be patterned over the epitaxial layer 311 having an opening over the surface of the epitaxial layer 311 where the photo-conversion device 23 (FIG. 3) is to be formed. An n-type dopant, such as phosphorus, arsenic, or antimony, may be implanted through the opening and into the epitaxial layer 311. Multiple implants may be used to tailor the profile of region 21. If desired, an angled implantation may be conducted to form the doped region 21, such that implantation is carried out at angles other than 90 degrees relative to the surface of the epitaxial layer 311.

As shown in FIG. 4D, the n-type region 21 is formed from a point adjacent the transfer gate stack 407 and extending in the epitaxial layer 311 between the gate stack 407 and the isolation region 37. The region 21 forms a photosensitive charge accumulating region for collecting photo-generated charge.

The doped surface layer 22 for the photo-conversion device 23 is implanted and formed as a highly doped p-type surface layer. A p-type dopant, such as boron, indium, or any other suitable p-type dopant, may be used to form the p-type surface layer 22. The p-type surface layer 22 may be formed by known techniques. For example, layer 22 may be formed by implanting p-type ions through openings in a layer of photoresist. Alternatively, layer 22 may be formed by a gas source plasma doping process, or by diffusing a p-type dopant into the epitaxial layer 311 from an in-situ doped layer or a doped oxide layer deposited over the area where layer 22 is to be formed.

The floating diffusion region 5 and source/drain region 2 are implanted by known methods, as also shown in FIG. 4D. The floating diffusion region 5 and source/drain region 2 are formed as n-type regions. Any suitable n-type dopant, such as phosphorus, arsenic, or antimony, may be used. The floating diffusion region 5 is formed on the side of the transfer gate stack 407 opposite the n-type photodiode region 21. The source/drain region 2 is formed on a side of the reset gate stack 406 opposite the floating diffusion region 5.

Conventional processing methods can be used to form other structures of the pixel cell 300. For example, insulating, shielding, and metallization layers to connect gate lines, and other connections to the pixel cell 300 may be formed. Also, the entire surface may be covered with a passivation layer (not shown) of, for example, silicon dioxide, borosilicate glass (BSG), phosphosilicate glass (PSG), or borophosphosilicate glass (BPSG), which is CMP planarized and etched to provide contact holes, which are then metallized to provide contacts. Conventional layers of conductors and insulators may also be used to interconnect the structures and to connect pixel 300 to peripheral circuitry.

While the above embodiments are described in connection with the formation of p-n-p-type photodiodes the invention is not limited to these embodiments. The invention also has applicability to other types of photo-conversion devices, such as a photodiode formed from n-p or n-p-n regions in a substrate, a photogate, or a photoconductor. If an n-p-n-type photodiode is formed the dopant and conductivity types of all structures would change accordingly. Specifically, the substrate 312 would be p-type and the epitaxial layer 311 would be n-type.

Although the above embodiments are described in connection with a 4T pixel cell 300, the configuration of pixel cell 300 is only exemplary and the invention may also be incorporated into other pixel circuits having different numbers of transistors. Without being limiting, such a circuit may include a three-transistor (3T) pixel cell, a five-transistor (5T) pixel cell, a six-transistor (6T) pixel cell, or a seven-transistor pixel cell (7T). A 3T cell often omits the transfer transistor, and may have a reset transistor adjacent to a photodiode. The 5T, 6T, and 7T pixel cells differ from the 4T pixel cell by the addition of one, two, or three transistors, respectively, such as a shutter transistor, a CMOS photogate transistor, and an anti-blooming transistor. Further, while the above embodiments are described in connection with a CMOS pixel cell 300 the invention is also applicable to pixel cells in a charge coupled device (CCD) image sensor.

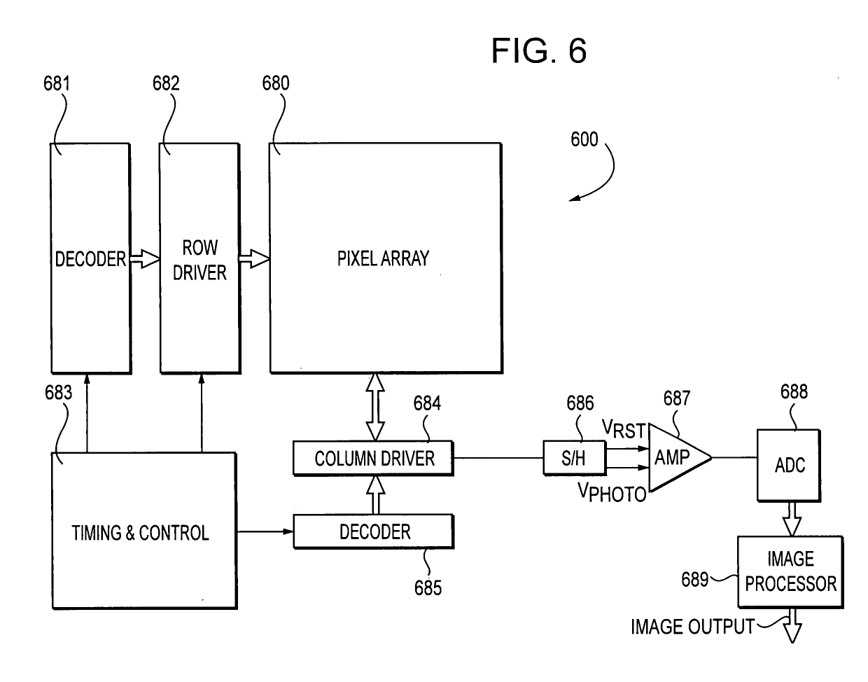

A typical single chip CMOS image sensor 600 is illustrated by the block diagram of FIG. 6. The image sensor 600 includes a pixel cell array 680 having one or more pixel cells 300 (FIG. 3) described above. The pixel cells of array 680 are arranged in a predetermined number of columns and rows.

The rows of pixel cells in array 680 are read out one by one. Accordingly, pixel cells in a row of array 680 are all selected for readout at the same time by a row select line, and each pixel cell in a selected row provides a signal representative of received light to a readout line for its column. In the array 680, each column also has a select line, and the pixel cells of each column are selectively read out in response to the column select lines.

The row lines in the array 680 are selectively activated by a row driver 682 in response to row address decoder 681. The column select lines are selectively activated by a column driver 684 in response to column address decoder 685. The array 680 is operated by the timing and control circuit 683, which controls address decoders 681, 685 for selecting the appropriate row and column lines for pixel signal readout.

The signals on the column readout lines typically include a pixel reset signal (Vᵣₛₜ) and a pixel image signal (Vₚₕₒₜₒ) for each pixel cell. Both signals are read into a sample and hold circuit (S/H) 686 in response to the column driver 684. A differential signal (Vᵣₛₜ-Vₚₕₒₜₒ) is produced by differential amplifier (AMP) 687 for each pixel cell, and each pixel cell's differential signal is digitized by analog-to-digital converter (ADC) 688. The analog-to-digital converter 688 supplies the digitized pixel signals to an image processor 689, which performs appropriate image processing before providing digital signals defining an image output.

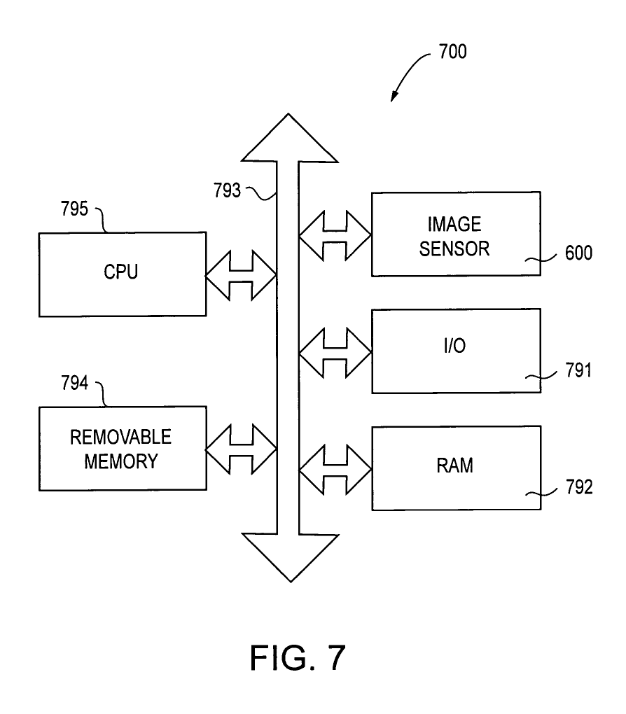

FIG. 7 illustrates a processor-based system 700 including the image sensor 600 of FIG. 6. The processor-based system 700 is exemplary of a system having digital circuits that could include image sensor devices. Without being limiting, such a system could include a computer system, camera system, scanner, machine vision, vehicle navigation, video phone, surveillance system, auto focus system, star tracker system, motion detection system, and other systems requiring image acquisition.

The processor-based system 700, for example a camera system, generally comprises a central processing unit (CPU) 795, such as a microprocessor, that communicates with an input/output (I/O) device 791 over a bus 793. Image sensor 600 also communicates with the CPU 795 over bus 793. The processor-based system 700 also includes random access memory (RAM) 792, and can include removable memory 794, such as flash memory, which also communicate with CPU 795 over the bus 793. Image sensor 600 may be combined with a processor, such as a CPU, digital signal processor, or microprocessor, with or without memory storage on a single integrated circuit or on a different chip than the processor.

It is again noted that the above description and drawings are exemplary and illustrate preferred embodiments that achieve the objects, features and advantages of the present invention. It is not intended that the present invention be limited to the illustrated embodiments. Any modification of the present invention which comes within the spirit and scope of the following claims should be considered part of the present invention.

What is claimed as new and desired to be protected by Letters Patent of the United States is:

1. A pixel cell comprising:
a substrate of a first conductivity type;
an epitaxial layer of a second conductivity type over the substrate, the epitaxial layer having a dopant gradient wherein a dopant concentration decreases from a first surface of the epitaxial layer adjacent the substrate to a second surface of the epitaxial layer opposite the substrate; and
a photo-conversion device at a surface of the epitaxial layer.

2. The pixel cell of claim 1, wherein the epitaxial layer has a thickness between about 2 μm and about 20 μm.

3. The pixel cell of claim 1, wherein the dopant concentration decreases uniformly in a linear manner from the first surface to then second surface.

4. The pixel cell of claim 1, wherein the dopant concentration decreases in a stepped manner from the first surface to then second surface.

5. The pixel cell of claim 1, wherein the dopant concentration of the substrate is about equal to or greater than about 1×10¹⁷ atoms/cm³.

6. The pixel cell of claim 1, wherein the dopant concentration of the epitaxial layer has a range of about 1×10¹⁴ atoms/cm³ to about 5×10¹⁸ atoms/cm³.

7. The pixel cell of claim 1, wherein the first conductivity type is n-type, and wherein the dopant concentration of at least a first portion of the substrate is between about 1×10¹⁷ atoms/cm³ and about 5×10¹⁸ atoms/cm³.

8. The pixel cell of claim 7, wherein the dopant concentration of a second portion of the substrate is between about 1×10¹⁴ atoms/cm³ and about 5×10¹⁷ atoms/cm³.

9. The pixel cell of claim 7, further comprising an epitaxial layer of the first conductivity type between the substrate and the epitaxial layer of a second conductivity type, wherein the dopant concentration of the epitaxial layer of the first conductivity type is between about 1×10¹⁴ atoms/cm³ and about 5×10¹⁷ atoms/cm³.

10. An image sensor comprising:
a substrate of a first conductivity type;
an epitaxial layer of a second conductivity type over the substrate, the epitaxial layer having a dopant gradient wherein a dopant concentration decreases from a first surface of the epitaxial layer adjacent the substrate to a second surface of the epitaxial layer opposite the substrate; and
an array of pixel cells, each pixel cell comprising a photo-conversion device at a surface of the epitaxial layer.

11. The image sensor of claim 10, wherein the epitaxial layer has a thickness between about 2 μm and about 20 μm.

12. The image sensor of claim 10, wherein the dopant concentration decreases uniformly in a linear manner from the first surface to then second surface.

13. The image sensor of claim 10, wherein the dopant concentration decreases in a stepped manner from the first surface to then second surface.

14. The image sensor of claim 10, wherein the dopant concentration of the substrate is about equal to or greater than about 1×10¹⁷ atoms/cm³.

15. The image sensor of claim 10, wherein the dopant concentration of the epitaxial layer has a range of about 1×10¹⁴ atoms/cm³ to about 5×10¹⁸ atoms/cm³.

16. The image sensor of claim 15, wherein the dopant concentration of the epitaxial layer has a range of about 1×10¹⁴ atoms/cm³ to about 5×10¹⁸ atoms/cm³.

17. The image sensor of claim 10, wherein the first conductivity type is n-type, and wherein the dopant concentration of at least a portion of the substrate is between about 1×10¹⁷ atoms/cm³ and about 5×10¹⁸ atoms/cm³.

18. A processor system comprising:
a processor; and
an image sensor coupled to the processor, the image sensor comprising:
a substrate of a first conductivity type;
an epitaxial layer of a second conductivity type over the substrate, the epitaxial layer having a dopant gradient wherein a dopant concentration decreases from a first surface of the epitaxial layer adjacent the substrate to a second surface of the epitaxial layer opposite the substrate; and
an array of pixel cells, at least one of the pixel cells comprising a photo-conversion device at a surface of the epitaxial layer.

19. The system of claim 18, wherein the epitaxial layer has a thickness between about 2 μm and about 20 μm.

20. The system of claim 18, wherein the dopant concentration decreases uniformly in a linear manner from the first surface to then second surface.

21. The system of claim 18, wherein the dopant concentration decreases in a stepped manner from the first surface to then second surface.

22. The system of claim 18, wherein the dopant concentration of the substrate is about equal to or greater than about 1×10¹⁷ atoms/cm³.

23. The system of claim 18, wherein the dopant concentration of the epitaxial layer has a range of about 1×10¹⁴ atoms/cm³ to about 5×10¹⁸ atoms/cm³.

24. The system of claim 18, wherein the first conductivity type is n-type, and wherein the dopant concentration of at least a portion of the substrate is between about 1×10¹⁷ atoms/cm³ and about 5×10¹⁸ atoms/cm³.

25. The system of claim 18, wherein the image sensor is a CCD-type image sensor.

26. The system of claim 18, wherein the image sensor is a CMOS image sensor.

27. A method of forming a pixel cell, the method comprising the acts of:
providing a substrate of a first conductivity type;
forming an epitaxial layer over the substrate;
doping the epitaxial layer to a second conductivity type, such that the epitaxial layer having a dopant gradient wherein a dopant concentration decreases from a first surface of the epitaxial layer adjacent the substrate to a second surface of the epitaxial layer opposite the substrate; and
forming a photo-conversion device at a surface of the epitaxial layer.

28. The method of claim 27, wherein the epitaxial layer is formed having a thickness between about 2 μm and about 20 μm.

29. The method of claim 27, wherein the epitaxial layer is doped such that the dopant concentration decreases uniformly in a linear manner from the first surface to then second surface.

30. The method of claim 27, wherein the epitaxial layer is doped such that the dopant concentration decreases in a stepped manner from the first surface to then second surface.

31. The method of claim 27, wherein the substrate is provided having a dopant concentration of about equal to or greater than about 1×10¹⁷ atoms/cm³.

32. The method of claim 27, wherein the epitaxial layer is doped such that the dopant concentration has a range of about 1×10¹⁴ atoms/cm³ to about 5×10¹⁸ atoms/cm³.

33. The method of claim 27, wherein the first conductivity type is n-type, and wherein the substrate is provided having a first portion having a dopant concentration between about 1×10¹⁷ atoms/cm³ and about 5×10¹⁸ atoms/cm³.

34. The pixel cell of claim 33, wherein the substrate is provided having a second portion having a dopant concentration between about 1×10¹⁴ atoms/cm³ and about 5×10¹⁷ atoms/cm³.

35. The method of claim 27, further comprising forming an epitaxial layer of the first conductivity type between the substrate and the epitaxial layer of a second conductivity type, wherein the dopant concentration of the epitaxial layer of the first conductivity type is between about 1×10¹⁴ atoms/cm³ and about 5×10¹⁷ atoms/cm³.
